(19) United States
(12) Patent Application Publication
(10) Pub. No.: US 2009/0065863 A1
(43) Pub. Date: Mar. 12, 2009

(54) LATERAL DOUBLE DIFFUSED METAL OXIDE SEMICONDUCTOR DEVICE

(75) Inventor: Il Yong PARK, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/171,636

(22) Filed: Jul. 11, 2008

(30) Foreign Application Priority Data
Sep. 12, 2007 (KR) 10-2007-0092597

(51) Int. Cl. H01L 29/78

(52) U.S. Cl. 257/343; 257/E29.256

(57) ABSTRACT

In one example embodiment, an LDMOS device includes a first n-type well formed on a p-type substrate, a plurality of isolation layers formed in the first n-type well, a p-type ion implantation region formed on a surface of each of the isolation layers, and a gate selectively formed on the first n-type well and the isolation layers.

### CROSS-REFERENCE TO A RELATED APPLICATION

This application claims the benefit of Korean Patent Application No. 10-2007-0092597, filed on Sep. 12, 2007 which is hereby incorporated by reference as if fully set forth herein.

### BACKGROUND

1. Field of the Invention

The present invention relates to a lateral double diffused metal oxide semiconductor (LDMOS) device.

2. Description of the Related Art

Conventional high-voltage lateral double diffused metal oxide semiconductor (LDMOS) devices include a silicon region between relatively narrow shallow trench isolation (STI) oxide layers. The relatively narrow STI oxide layers are generally formed using a dielectric reduced surface field (RESURF) technology resulting in a relatively high breakdown voltage. However, as current flows through the relatively narrow STI oxide layers when the device is turned on, on-resistance is also relatively high.

### SUMMARY OF EXAMPLE EMBODIMENTS

In general, example embodiments of the invention relate to a lateral double diffused (LD) MOS device having a relatively high breakdown voltage and a relatively low on-resistance.

In one example embodiment, an LDMOS device includes a first n-type well formed on a p-type substrate, a plurality of isolation layers formed in the first n-type well, a p-type ion implantation region formed on a surface of each of the isolation layers, and a gate selectively formed on the first n-type well and the isolation layers.

In another example embodiment, an LDMOS device includes an n-type well formed on a p-type substrate, a p-type well formed on the n-type well, a plurality of isolation layers formed in the p-type well, and a gate selectively formed on the p-type well and the isolation layers.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

Example embodiments of the present invention will be disclosed in the following description of example embodiments given in conjunction with the accompanying drawings, in which:

FIG. 1 is a perspective of a portion of an example LDMOS device;

FIG. 2 is a plan view of the example LDMOS of FIG. 1;

FIG. 3 is a cross-sectional side view of example LDMOS device of FIGS. 1 and 2; and

FIG. 4 is a cross-sectional side vide of another example LDMOS device.

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

As used herein, it is understood that when a layer is referred to as being “on” or “under” another layer or substrate, it can be directly on or under the other layer or substrate, or intervening layers may also be present. Further, the n-type and p-type layers discussed below can generally be reversed.

### First Example LDMOS Device

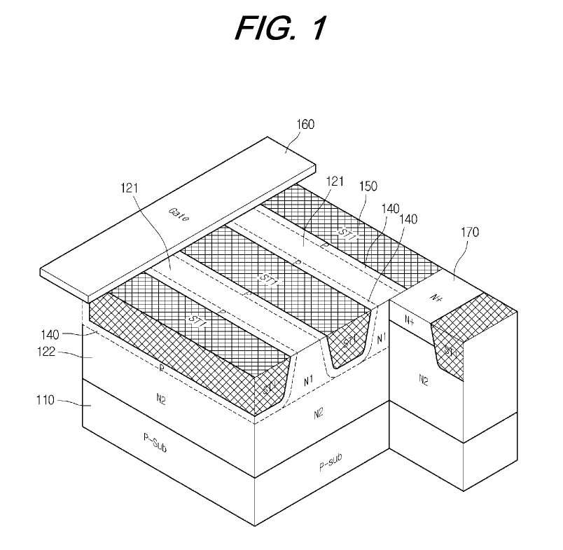

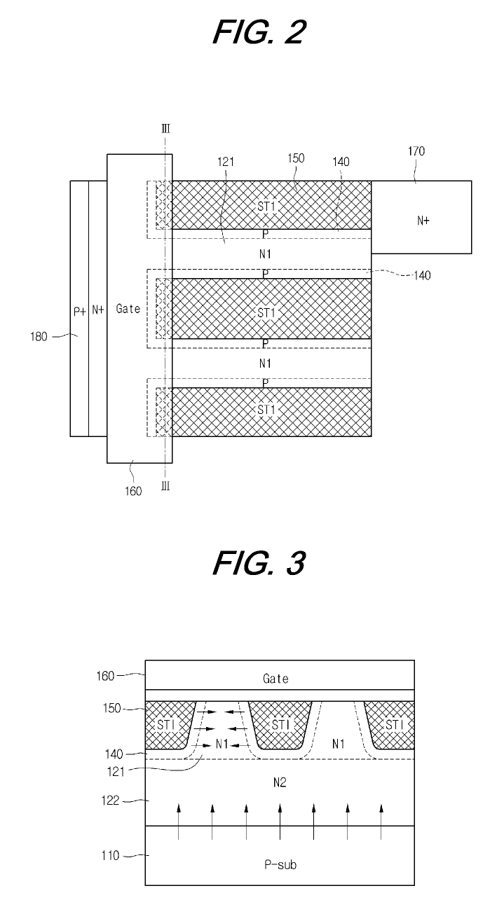

FIGS. 1-3 disclose aspects of a first example LDMOS device. In particular, FIG. 1 is a perspective view of a portion of the first example LDMOS device, FIG. 2 is a plan view of a portion of the first example LDMOS device, and FIG. 3 is a cross-sectional side view of the first example LDMOS device along the line III-III of FIG. 2.

With reference to FIGS. 1-3, the first example LDMOS device includes an n-type well 121 formed on a p-type substrate 110, a plurality of isolation layers 150 formed in the n-type well 121, a p-type ion implantation region 140 formed on the surface of the isolation layers 150, and a gate 160 selectively formed on the n-type well 121 and the isolation layers 150. A drain 170 and a source 180 can be formed on either sides of the gate 160. The p-type ion implantation region 140 can further be formed to surround the isolation layers 150.

In the first example LDMOS device of FIGS. 1-3, an STI process is employed to form the p-type ion implantation region 140 on the surface of the isolation layers 150 such that the breakdown voltage of the first example LDMOS device is increased and the on-resistance of the first example LDMOS device is reduced. In particular, unlike conventional dielectric reduce surface field (RESURF) technology which results in relatively narrow isolation layers, the first example LDMOS device is formed using a depletion phenomenon in the p-n junction which results in relatively wide isolation layers 150. In addition, unlike conventional RESURF technology, the STI process makes it possible to prevent the moving distance of electronic current from increasing which results in a relatively low on-resistance in the first example LDMOS device.

In the first example LDMOS device, the p-type ion implantation region 140 is formed on the isolation layers 150. The increased width of the isolation layers 150 results in the n-type well 121 serving as an active region between the isolation layers 150. Therefore, in an on state, the relatively wide width of the active region allows a relatively large amount of electronic current to flow so that the on-resistance of the first example LDMOS device is relatively low. In an off state, a depletion layer is formed between the p-type ion implantation region 140 and the n-type first well 121 so that the breakdown voltage is relatively high.

The first example LDMOS device may include only the n-type well N1 121 formed in a drift region. Alternatively, the first example LDMOS device may include both the n-type well N1 121 and a second n-type well N2 122 formed in the drift region.

As illustrated in FIG. 3, when the first example LDMOS device includes both the first n-type well 121 and the second n-type well 122, mutual depletion is generated from the both p-type regions 140 in the case of the n-type first well 121. Since a depletion layer between a p-sub 110 and the n-type second well 122 increases in the case of the n-type second well 122, it is possible for the drift region to be completely depleted.

In addition, the doping densities of the first n-type well 121 and the second n-type well 122 may be controlled so that a relatively high breakdown voltage can be maintained. For example, as current may be large on the surface of a substrate, the doping density of the first n-type well 121 may be greater than the doping density of the second n-type well 122 so that performance can be improved. In addition, the doping density of the p-type ion implantation region 140 may be greater than the doping density of the p-type substrate 110 so that depletion can be actively generated.

In the first example LDMOS device, as illustrated in FIG. 2, the device isolation layers 150 and the n-type first well 121 can be alternately formed between the gate 160 and the drain 170. For example, an orientation of the isolation layers 150 and the first n-type well 121 may be generally perpendicular to an orientation of the gate 160.

### Second Example LDMOS Device

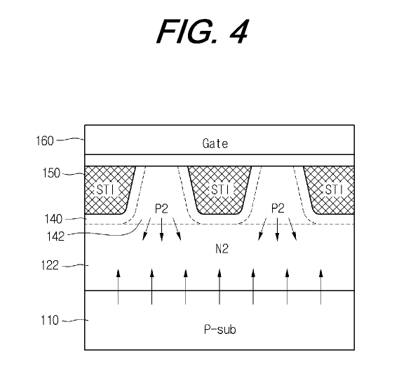

FIG. 4 is a sectional view of a portion of a second example LDMOS device. The second example LDMOS device may include the n-type well 122 formed on the p-type substrate 110, a p-type well 142 formed on the n-type well 122, a plurality of isolation layers 150 formed in the p-type well 142, and the gate 160 selectively formed on the p-type well 142 and the isolation layers 150.

The second example LDMOS device may adopt the technological characteristics of the first example LDMOS device. However, the second example LDMOS device differs from the first example LDMOS device in that the p-type well 142 of the second example LDMOS device is formed in place of the n-type first well 122 of the first example LDMOS device. Therefore, the surface of the substrate becomes p-type so that it is possible to prevent electrons from flowing on the surface of the substrate and to prevent electrons from being trapped in the isolation layers.

In the second example LDMOS device, depletion is transmitted from the p-type substrate 110 and the p-type well 142 to the n-type well 122 so that it is possible to substantially secure depletion.

In addition, in the second example LDMOS device, the p-type ion implantation region 140 that surrounds the isolation layers is further formed between the isolation layers 150 and the p-type well 142 so that it is possible to prevent the isolation layers 150 and the n-type second well 122 from directly contacting and to rapidly perform depletion.

Although example embodiments of the present invention have been shown and described, changes might be made in these example embodiments. The scope of the invention is therefore defined in the following claims and their equivalents.

What is claimed is:

1. An LDMOS device, comprising:
a first n-type well formed on a p-type substrate;
a plurality of isolation layers formed in the first n-type well;
a p-type ion implantation region formed on a surface of each of the isolation layers; and
a gate selectively formed on the first n-type well and the isolation layers.

2. The LDMOS device of claim 1, further comprising a second n-type well formed between the first n-type well and the p-type substrate.

3. The LDMOS device of claim 2, wherein a doping density of the first n-type well is greater than a doping density of the second n-type well.

4. The LDMOS device of claim 1, wherein the p-type ion implantation region surrounds the isolation layers.

5. The LDMOS device of claim 1, wherein the p-type ion implantation region is formed between the first n-type well and the isolation layers.

6. The LDMOS device of claim 1, wherein the isolation layers and the first n-type well are alternately formed between the gate and a drain.

7. The LDMOS device of claim 6, wherein an orientation of the isolation layers and the first n-type well is generally perpendicular to an orientation of the gate.

8. The LDMOS device of claim 1, wherein a doping density of the p-type ion implantation region is greater than a doping density of the p-type substrate.

9. An LDMOS device, comprising:
an n-type well formed on a p-type substrate;
a p-type well formed on the n-type well;
a plurality of isolation layers formed in the p-type well; and
a gate selectively formed on the p-type well and the isolation layers.

10. The LDMOS device of claim 9, further comprising a p-type ion implantation region formed on a surface of each of the isolation layers.

11. The LDMOS device of claim 10, wherein the p-type ion implantation region surrounds the isolation layers.

12. The LDMOS device of claim 10, wherein the p-type ion implantation region is formed between the p-type well and the isolation layers.

13. The LDMOS device of claims 9, wherein the isolation layers and the p-type well are alternately formed between the gate and a drain.
